(19) United States
(12) Patent Application Publication
(10) Pub. No.: US 2026/0230097 A1
(43) Pub. Date: Aug. 6, 2026

(54) Transmitter for re-driver using all-CMOS process

(71) Applicant: NOVATEK Microelectronics Corp., Hsin-Chu (TW)

(72) Inventors: Chen-Wei Huang, Hsinchu City (TW); Jr-Ching Lin, Hsinchu County (TW); Chun-Chi Chang, Hsinchu City (TW)

(73) Assignee: NOVATEK Microelectronics Corp., Hsin-Chu (TW)

(21) Appl. No.: 19/433,997

(22) Filed: Dec. 29, 2025

Related U.S. Application Data
(60) Provisional application No. 63/754,580, filed on Feb. 6, 2025.

(30) Foreign Application Priority Data
Jun. 20, 2025 (TW) 114123234

(51) Int. Cl. H04B 1/04; H03K 17/16

(52) U.S. Cl. CPC H04B 1/0475; H03K 17/165; H03K 2217/0036; H03K 2217/0063; H03K 2217/0081; H04B 2001/0416

(57) ABSTRACT

A transmitter includes first and second transistors, a capacitor, a resistor, first and second load resistors, and a current source. The first transistor has a gate terminal to receive a first input signal and a first terminal to output a second output signal. The second transistor has a gate terminal to receive a second input signal and a first terminal to output a first output signal. The capacitor and the resistor are coupled between a second terminal of the first transistor and a second terminal of the second transistor. The first load resistor is coupled between the first terminal of the first transistor and a first node. The second load resistor is coupled between the first terminal of the second transistor and the first node. The current source is coupled to the first terminal of the first transistor, the first terminal of the second transistor, and/or the first node.

### CROSS REFERENCE TO RELATED APPLICATIONS

This application claims the benefit of U.S. Provisional Application No. 63/754,580, filed on Feb. 6, 2025. The content of the application is incorporated herein by reference.

### BACKGROUND OF THE INVENTION

### 1. Field of the Invention

The present invention relates to a transmitter, and more particularly, to a transmitter for a re-driver.

### 2. Description of the Prior Art

With the explosion of information nowadays, the amount of data transmitted in an electronic system is getting larger and larger, and the transmission rate is getting faster and faster. Signals in high-speed transmission easily attenuate after propagating a certain distance, and thus there is a need to develop a re-driver (or re-timer) to be used as a repeater deployed on the signal transmission path, to compensate for the attenuations of the high-speed signals. A linear re-driver can provide a higher linearity for the signals, and thus is usually used to realize the re-driver circuit.

However, the linear re-driver has a high demand for signal swing linearity. Traditionally, the linear re-driver is mostly implemented by using the bipolar complementary metal-oxide semiconductor (BiCMOS) process to gain the benefits of high transconductance (gm) of bipolar junction transistor (BJT) devices. However, the BJT has a disadvantage that its voltage headroom requirement is much higher than the voltage headroom requirement of a complementary metal-oxide semiconductor (CMOS) device. This is contrary to the trends of pursuing low voltage supply and low power consumption nowadays.

### SUMMARY OF THE INVENTION

It is therefore an objective of the present invention to provide a transmitter for a re-driver implemented with an all complementary metal-oxide semiconductor (all-CMOS) process.

An embodiment of the present invention discloses a transmitter, which comprises a first transistor, a second transistor, a capacitor, a resistor, a first load resistor, a second load resistor and a current source. The first transistor comprises a first terminal, a second terminal and a gate terminal, wherein the gate terminal of the first transistor is configured to receive a first input signal and the first terminal of the first transistor is configured to output a second output signal. The second transistor comprises a first terminal, a second terminal and a gate terminal, wherein the gate terminal of the second transistor is configured to receive a second input signal and the first terminal of the second transistor is configured to output a first output signal. The capacitor is coupled between the second terminal of the first transistor and the second terminal of the second transistor. The resistor is coupled between the second terminal of the first transistor and the second terminal of the second transistor. The first load resistor is coupled between the first terminal of the first transistor and a first node. The second load resistor is coupled between the first terminal of the second transistor and the first node. The current source is coupled to at least one of the first terminal of the first transistor, the first terminal of the second transistor, and the first node.

Another embodiment of the present invention discloses a re-driver, which comprises an equalizer, a gain amplifier and a transmitter. The gain amplifier is coupled to the equalizer. The transmitter is coupled to the gain amplifier and comprises a first transistor, a second transistor, a capacitor, a resistor, a first load resistor, a second load resistor and a current source. The first transistor comprises a first terminal, a second terminal and a gate terminal, wherein the gate terminal of the first transistor is configured to receive a first input signal and the first terminal of the first transistor is configured to output a second output signal. The second transistor comprises a first terminal, a second terminal and a gate terminal, wherein the gate terminal of the second transistor is configured to receive a second input signal and the first terminal of the second transistor is configured to output a first output signal. The capacitor is coupled between the second terminal of the first transistor and the second terminal of the second transistor. The resistor is coupled between the second terminal of the first transistor and the second terminal of the second transistor. The first load resistor is coupled between the first terminal of the first transistor and a first node. The second load resistor is coupled between the first terminal of the second transistor and the first node. The current source is coupled to at least one of the first terminal of the first transistor, the first terminal of the second transistor, and the first node.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a transmitter.

FIG. 2 is a schematic diagram of a re-driver according to an embodiment of the present invention.

FIG. 3 illustrates a detailed implementation of the transmitter according to an embodiment of the present invention.

FIG. 4 is a schematic diagram of the small-signal model of the transmitter.

FIG. 5 illustrates the Bode plot corresponding to the small-signal model of the transmitter.

FIG. 6A to FIG. 6C are schematic diagrams of the current paths of the transmitter under different scenarios.

FIG. 7 is a schematic diagram of another transmitter according to an embodiment of the present invention.

FIG. 8 is a schematic diagram of a further transmitter according to an embodiment of the present invention.

FIG. 9 illustrates an implementation of the transmitter realized by using high-voltage devices and low-voltage devices.

### DETAILED DESCRIPTION

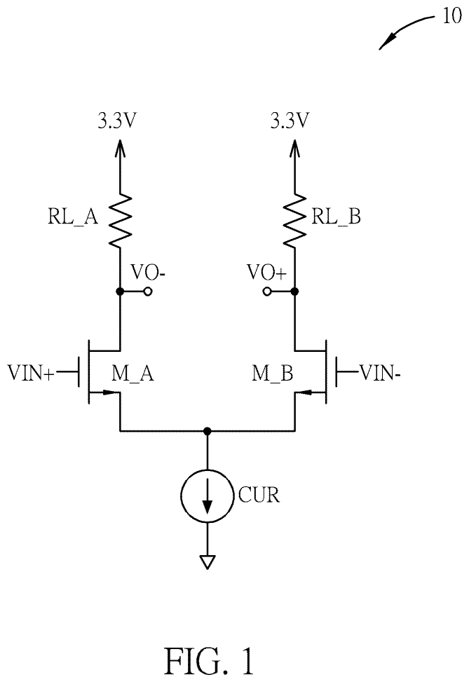

FIG. 1 is a schematic diagram of a transmitter 10. The transmitter 10 includes a current source CUR, two transistors M_A and M_B, and two load resistors RL_A and RL_B. The transistors M_A and M_B are configured to receive differential input signals VIN+ and VIN− to generate differential output signals VO+ and VO−. In general, the transistors M_A and M_B may be N-type metal-oxide semiconductor field-effect transistors (NMOSFETs) (abbreviated as NMOS transistors hereinafter) or NPN-type bipolar junction transistors (NPN BJTs). In FIG. 1, the transistors M_A and M_B are illustrated as NMOS transistors as an example. One terminal of the load resistors RL_A and RL_B is respectively coupled to the transistors M_A and M_B, and the other terminal is coupled to a power supply terminal for receiving a 3.3V supply voltage. In the structure of the transmitter 10, its gain G may be calculated as follows:

$$G = {g}_{m} {R}_{L} ; \qquad ( 1 )$$

where R_{L} is the resistance value of the load resistors RL_A and RL_B, and gₘ is the transconductance value of the transistors M_A and M_B.

If the transistors M_A and M_B are implemented with NMOS transistors, the transconductance value gₘ of the MOS transistors is relatively small, making it difficult to achieve high signal gain and bandwidth. In addition, the input operation range of MOS transistors is narrower, and thus it is not feasible to use the structure of the transmitter 10 to achieve high linearity. On the other hand, if the transistors M_A and M_B are implemented with NPN BJTs, although they have higher transconductance value, a larger voltage headroom is required. Consequently, a larger supply voltage (e.g., 3.3V) should be used, making low-voltage applications impractical. Moreover, if the transmitter 10 operates under large supply voltage variations, the voltage may easily exceed the tolerable range of the transistors M_A and M_B to cause damages. Therefore, this structure is also unsuitable for high voltage range applications.

Therefore, the present invention provides a transmitter structure implemented by using an all-complementary metal-oxide semiconductor (all-CMOS) process, to be applied to re-drivers. Under the all-CMOS process, no BJTs are used, thereby avoiding the issues related to voltage headroom. This enables support for a lower supply voltage level to achieve a wider operation voltage range, while reducing additional circuit costs required by the BJT process. In addition, through well-designed circuitry, the transmitter structure of the present invention may achieve high linearity in the signal output.

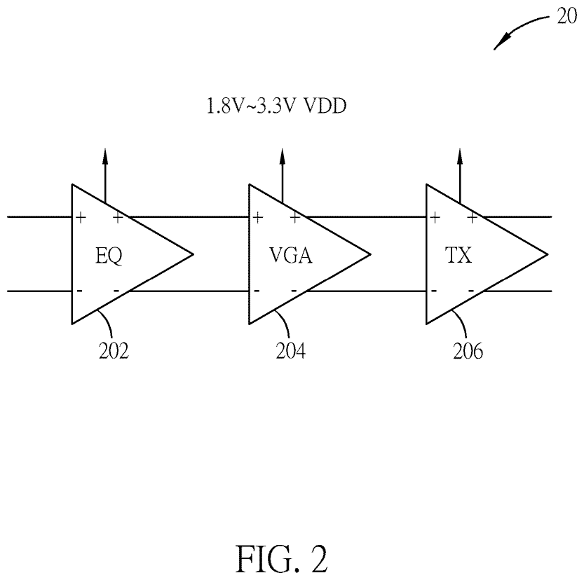

FIG. 2 is a schematic diagram of a re-driver 20 according to an embodiment of the present invention. The re-driver 20 includes an equalizer (EQ) 202, a variable gain amplifier (VGA) 204 and a transmitter (TX) 206. The signals received by the re-driver 20 are first processed by the equalizer 202, which is configured to compensate for high-frequency attenuations on the received signals. The VGA 204 is configured to amplify the signal swing while maintaining the linearity of the signals. After the compensation and amplification operations, the transmitter 206 outputs the signals with sufficient driving capability. In addition, the design of the transmitter 206 should also be adapted to the requirement of impedance matching.

As shown in FIG. 2, the re-driver 20 may support a wide range of supply voltage VDD from 1.8V to 3.3V. Note that if the transmitter 10 in FIG. 1 applies the bipolar complementary metal-oxide semiconductor (BiCMOS) process, it can only support a high supply voltage 3.3V due to the voltage headroom issue of BJTs. In comparison, the re-driver 20 and the transmitter 206 of the present invention may be implemented in the all-CMOS process, and thus could support a lower supply voltage VDD (such as 1.8V) and a wider voltage range.

As for the requirement of high linearity, the equalizer 202, which may be a continuous time linear equalizer (CTLE), for example, may apply source degeneration to compensate for the high-frequency attenuation of signals, where the source degeneration with large resistance may also improve the signal linearity. The linearity of the VGA 204 may be improved through other circuit techniques. The present invention provides a novel circuit structure for the transmitter 206, to improve the linearity of signal swing, while satisfying the requirement of a wide range operation voltage.

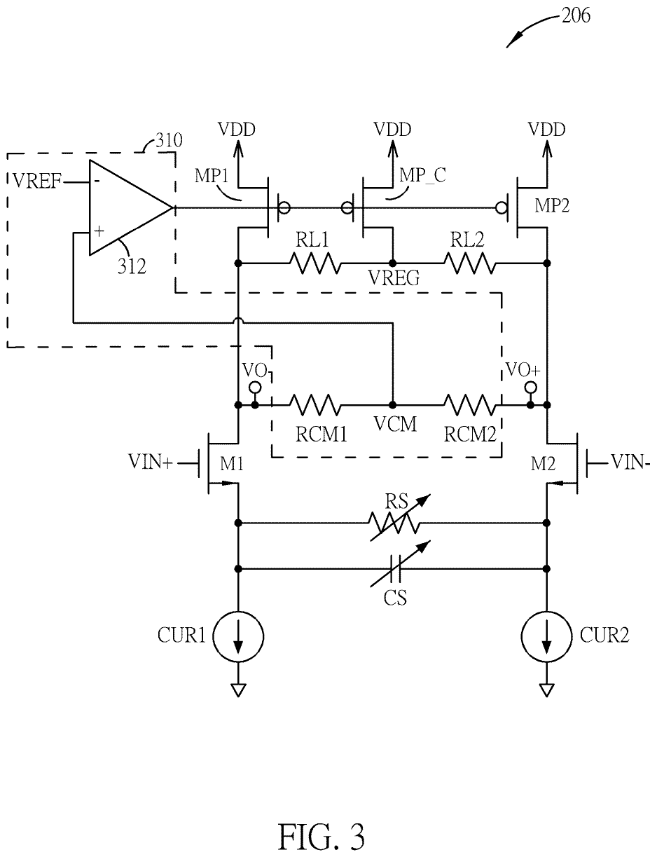

FIG. 3 illustrates a detailed implementation the transmitter 206 according to an embodiment of the present invention. The transmitter 206 may receive differential input signals VIN+ and VIN− from the VGA 204, to generate and output differential output signals VO+ and VO−. In detail, the transmitter 206 includes transistors M1 and M2, a bandwidth extension capacitor CS, a source degeneration resistor RS, load resistors RL1 and RL2, high-side current sources MP1, MP2 and MP_C, low-side current sources CUR1 and CUR2, and a common mode control circuit 310. The transistors M1 and M2 may be implemented by using the NMOS transistors for signal transmissions, where the transistor M1 may receive the input signal VIN+ through its gate terminal and output the output signal VO− through its drain terminal, and the transistor M2 may receive the input signal VIN− through its gate terminal and output the output signal VO+ through its drain terminal. The drain terminal of the transistor M1 and the drain terminal of the transistor M2 are coupled to the high-side current sources MP1 and MP2, respectively. The source terminal of the transistor M1 and the source terminal of the transistor M2 are coupled to the low-side current sources CUR1 and CUR2, respectively. The bandwidth extension capacitor CS is coupled between the source terminal of the transistor M1 and the source terminal of the transistor M2. The source degeneration resistor RS is also coupled between the source terminal of the transistor M1 and the source terminal of the transistor M2. The load resistor RL1 is coupled between the drain terminal of the transistor M1 and a regulation node VREG, and the load resistor RL2 is coupled between the drain terminal of the transistor M2 and the regulation node VREG. The regulation node VREG is further coupled to the high-side current source MP_C. The high-side current sources MP1, MP2 and MP_C and the low-side current sources CUR1 and CUR2 may provide currents required by the transistors M1 and M2 for operations. Each of the high-side current sources MP1, MP2 and/or MP_C may be implemented by using a transistor (as shown in FIG. 3), but not limited thereto.

In addition, the common mode control circuit 310 includes an operational amplifier 312 and common mode feedback resistors RCM1 and RCM2. The common mode feedback resistor RCM1 is coupled between the drain terminal of the transistor M1 and a common mode node, and the common mode feedback resistor RCM2 is coupled between the drain terminal of the transistor M2 and the common mode node. The common mode node is further coupled to the positive input terminal of the operational amplifier 312. The negative input terminal of the operational amplifier 312 is coupled to a reference voltage source for receiving a reference voltage VREF. This reference voltage source may be implemented in any suitable manner, such as using a bandgap reference voltage generation circuit. The output terminal of the operational amplifier 312 is coupled to the high-side current sources MP1, MP2 and MP_C, for providing the necessary bias voltage for the high-side current sources MP1, MP2 and MP_C. In general, the common mode feedback resistors RCM1 and RCM2 may be designed to have equal resistance value, so that the common mode voltage VCM of the output signals VO+ and VO− equals the voltage at the common mode node. Through the control of the operational amplifier 312, the common mode voltage VCM is equal to the reference voltage VREF. As a result, through the well-controlled level of the reference voltage VREF, the output signals VO+ and VO− can swing around the predetermined common mode voltage VCM, and are not affected by the level of the supply voltage VDD. This allows the transmitter 206 to support a wide range of the supply voltage VDD.

Note that the transmitter 206 applies the all-CMOS process. Therefore, the transistors M1 and M2 used for signal transmission may be NMOS transistors, whose transconductance value is generally lower than the transconductance value of BJTs. As a result, the linearity and bandwidth achievable by the transistors are relatively poor. To solve this problem, the present invention incorporates additional circuit structure designs to enhance both the linearity and bandwidth.

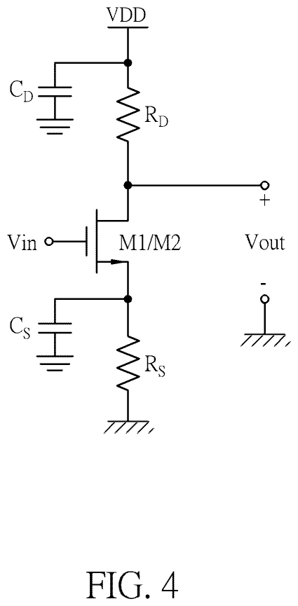

As shown in FIG. 2, the source degeneration resistor RS is deployed on the source terminals of the transistors M1 and M2, to improve the linearity of the output signals VO+ and VO−. According to the voltage-current conversion formula of the transistors, when the transconductance value is infinitely large, the signal gain is entirely determined by the resistance, resulting in perfectly linear behavior. If the transmitter structure uses BJTs which usually have higher transconductance values, high linearity is more easily achieved. However, the transmitter 206 of the present invention applies MOS transistors as the signal transmission transistors M1 and M2, which have lower transconductance values. Therefore, the linearity could be improved by including the source degeneration resistor RS on the source terminals of the transistors M1 and M2. Further details and formulas will be provided in FIG. 4 and related paragraphs. In some embodiments, the source degeneration resistor RS may be a variable resistor, or may be composed of one or more of multiple resistors connected in series or parallel to achieve an adjustable resistance value, so as to achieve the optimal balance between gain and linearity.

In addition, the bandwidth extension capacitor CS is also deployed on the source terminals of the transistors M1 and M2. Since the re-driver 20 of the present invention is mainly intended for high-speed signal transmission, and the transmission lines often have significant high-frequency impedance, this results in substantial attenuation of high-frequency signals. Therefore, the transmitter 206 is requested to provide sufficient bandwidth to meet the demands of high-speed transmission. The bandwidth extension capacitor CS serves to increase the bandwidth of the transmitter 206 to fulfill this purpose.

Note that in this disclosure, the names bandwidth extension capacitor CS and source degeneration resistor RS are merely functional designations. The naming is intended to distinguish them from other capacitors/resistors that may appear in the system or circuit, and is not meant to limit the functions of the capacitor or resistor.

FIG. 4 is a schematic diagram of the small-signal model of the transmitter 206, illustrating the resistances and capacitances observed on the signal transmission path. In detail, the transmitter 206 may receive an input signal Vin (which may represent the input signal VIN+ or VIN− in FIG. 3 or the differential value of them), and output an output signal Vout (which may represent the output signal VO+ or VO− in FIG. 3 or the differential value of them). The transistor on the signal path may represent the transistor M1 or M2 in FIG. 3. The signal gain (Vout/Vin) may be influenced by the capacitance C_{D} and the resistance R_{D} observed on the drain terminal of the transistor M1/M2, and may also be influenced by the capacitance C_{S} and the resistance R_{S} observed on the source terminal of the transistor M1/M2. In the transmitter 206, the resistance R_{D} on the drain terminal of the transistor M1/M2 mainly comes from the contributions of the load resistors RL1 and RL2, and the capacitance C_{D} mainly comes from the contributions of the load capacitance on the output channel and also includes other parasitic capacitances on the signal output terminal, such as the parasitic capacitance of the transistors M1 and/or M2 and the parasitic capacitance of the high-side current sources MP1 and/or MP2. The resistance R_{S} on the source terminal of the transistor M1/M2 mainly comes from the contributions of the source degeneration resistor RS, and the capacitance C_{S} mainly comes from the contributions of the bandwidth extension capacitor CS and also includes other parasitic capacitances on the source terminal.

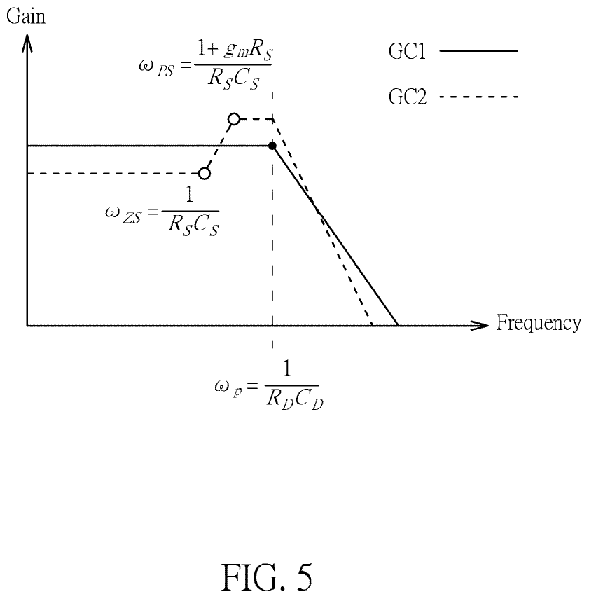

FIG. 5 illustrates the Bode plot corresponding to the small-signal model of the transmitter 206, for showing the relationship between gain and frequency. First, based on the small-signal model shown in FIG. 4, the DC gain of the signal may be calculated as follows:

$$\frac{Vout}{Vin} = - \frac{{g}_{m} {R}_{D}}{1 + {g}_{m} {R}_{S}} = - \frac{{R}_{D}}{\frac{1}{{g}_{m}} + {R}_{S}} ; \qquad ( 2 )$$

where gₘ is the transconductance value of the transistor M1/M2.

From Equation (2), it can be seen that the linearity of the gain reaches its maximum when the transconductance value gₘ approaches infinity, and decreases as the transconductance value gₘ becomes smaller. In other words, when the transconductance value gₘ is getting larger, the gain is closer to R_{D}/R_{S}, which indicates higher linearity. The present invention applies MOS transistors to implement the signal transmission transistors M1 and M2 in the transmitter 206. Although the transconductance value gₘ of the signal transmission transistors M1 and M2 is smaller, the linearity of the output signal Vout may still be improved through the inclusion of the source degeneration resistor RS. In addition, as shown in FIG. 5, although the source degeneration resistor RS slightly reduces the DC gain of the signal, the overall gain of the re-driver 20 primarily comes from the VGA 204. Therefore, this issue could be mitigated by increasing the gain of the VGA 204.

FIG. 5 illustrates the gain curves under two different scenarios, where GC1 represents the gain curve formed by other components in the transmitter 206 without the inclusion of the source degeneration resistor RS and the bandwidth extension capacitor CS, and GC2 represents the gain curve of the transmitter 206 when the source degeneration resistor RS and the bandwidth extension capacitor CS are included.

When the source degeneration resistor RS and the bandwidth extension capacitor CS are not present, the gain curve GC1 may exhibit a low-pass filter-like behavior. Its dominant pole appears at the frequency ωₚ, and the value of the frequency ωₚ is equal to ωₚ=1/R_{D}C_{D}, Which is determined by the capacitance C_{D} and resistance R_{D}. In general, in order to increase the bandwidth, the most intuitive approach is to raise the frequency ωₚ, thereby pushing the dominant pole to a higher frequency. This could be achieved by reducing the value of the capacitance C_{D} or resistance R_{D}. However, as mentioned above, the capacitance C_{D} mainly comes from the load capacitance on the output channel and is difficult to be reduced through circuit design approaches. The resistance R_{D} mainly comes from the contributions of the load resistors RL1 and RL2, which must satisfy the impedance matching requirement of 50 ohms and thus their values cannot be arbitrarily changed to adjust the bandwidth.

Therefore, in addition to adding the source degeneration resistor RS to improve the linearity, the bandwidth extension capacitor CS may also be included on the source terminals of the transistors M1 and M2 in the transmitter 206 to increase the signal bandwidth. As shown in FIG. 5, with proper design of the bandwidth extension capacitor CS and the source degeneration resistor RS, another pole (at frequency ω_{PS}) and zero (at frequency ω_{ZS}) could be introduced at lower frequencies, so as to form the gain-frequency relationship of the transmitter 206 as the gain curve GC2. The newly introduced pole frequency ω_{PS} and zero frequency ω_{ZS} are given by:

$${ω}_{PS} = \frac{1 + {g}_{m} {R}_{S}}{{R}_{S} {C}_{S}} ;$$

$${ω}_{ZS} = \frac{1}{{R}_{S} {C}_{S}} .$$

Since the pole frequency ω_{PS} generated by the bandwidth extension capacitor CS is lower than the pole frequency ωₚ at the transistor's drain terminal, ω_{PS} may replace ωₚ as the dominant pole. This pole frequency ω_{PS} together with the zero frequency ω_{ZS} may alter the frequency response of signals and enhance the peak gain, thereby achieving the effect of bandwidth extension, as illustrated in FIG. 5. In some embodiments, the bandwidth extension capacitor CS may be a variable capacitor, of which the capacitance may be flexibly adjusted to optimize the bandwidth setting.

In order to meet the requirements of a wide range of the supply voltage VDD, the transmitter 206 of the present invention incorporates the high-side current sources MP1, MP2 and MP_C, which may be implemented by using P-type metal-oxide semiconductor field-effect transistor (PMOSFETs) (abbreviated as PMOS transistors hereinafter). The source terminals of the transistors of the high-side current sources MP1, MP2 and MP_C are coupled to the power supply terminal to receive the supply voltage VDD, and the drain terminals of the transistors of the high-side current sources MP1, MP2 and MP_C are respectively coupled to the drain terminal of the signal transmission transistor M1, the drain terminal of the signal transmission transistor M2 and the regulation node VREG. In general, the high-side current sources MP1, MP2 and MP_C require transistors with larger dimensions to withstand the higher supply voltage VDD. However, larger transistors are accompanied by larger parasitic capacitance. Therefore, if the high-side current source MP_C is omitted and only the high-side current sources MP1 and MP2 are used to supply currents, the high-side current sources MP1 and MP2 should be designed larger, resulting in greater parasitic capacitance at the drain terminals of the transistors M1 and M2 (i.e., the signal output terminals). This increases the capacitive load that the transistors M1 and M2 are requested to drive when outputting signals, thereby limiting the signal transmission speed. From the frequency response perspective (see FIG. 5), the increase in parasitic capacitance at the drain terminals of the transistor M1/M2 refers to an increase in the value of the capacitance C_{D}, which may reduce the pole frequency wp and leads to a decrease in bandwidth.

On the other hand, if the high-side current sources MP1 and MP2 are omitted and only the central high-side current source MP_C is used to supply currents, the regulation node VREG to which the high-side current source MP_C is connected remains stable and would not fluctuate with the output signals VO+ and VO−. As a result, the output signals VO+ and VO− may not be affected by the parasitic capacitance of the high-side current source MP_C, thereby minimizing the capacitive load. However, under this structure, all the current required for the operations of the transmitter 206 has to pass through the load resistors RL1 and/or RL2 to be supplied to the transistors M1 and M2. The excessive current flowing through the load resistors RL1/RL2 may cause a significant voltage drop, which results in a loss of voltage headroom. When the supply voltage VDD is relatively low, this may cause that the high-side current source MP_C cannot function normally, thereby affecting the range of the supply voltage VDD.

Therefore, in order to meet the requirements of a wide range of the supply voltage VDD while achieving sufficient bandwidth for driving high-speed signals, the transmitter 206 of the present invention is equipped with three high-side current sources MP1, MP2 and MP_C. Each high-side current source provides a portion of the current required for the operations of the transmitter 206. The inclusion of the high-side current source MP_C helps reduce the parasitic capacitance on the signal output terminals, thereby enhancing signal bandwidth. Meanwhile, the inclusion of the high-side current sources MP1 and MP2 helps reduce the current flowing through the load resistors RL1/RL2, thereby alleviating the voltage headroom problem and thus expanding the operation voltage range of the transmitter 206 (i.e., the range of the supply voltage VDD). Through well design of the high-side current sources MP1, MP2 and MP_C, an optimal trade-off between the voltage headroom and signal bandwidth may be achieved.

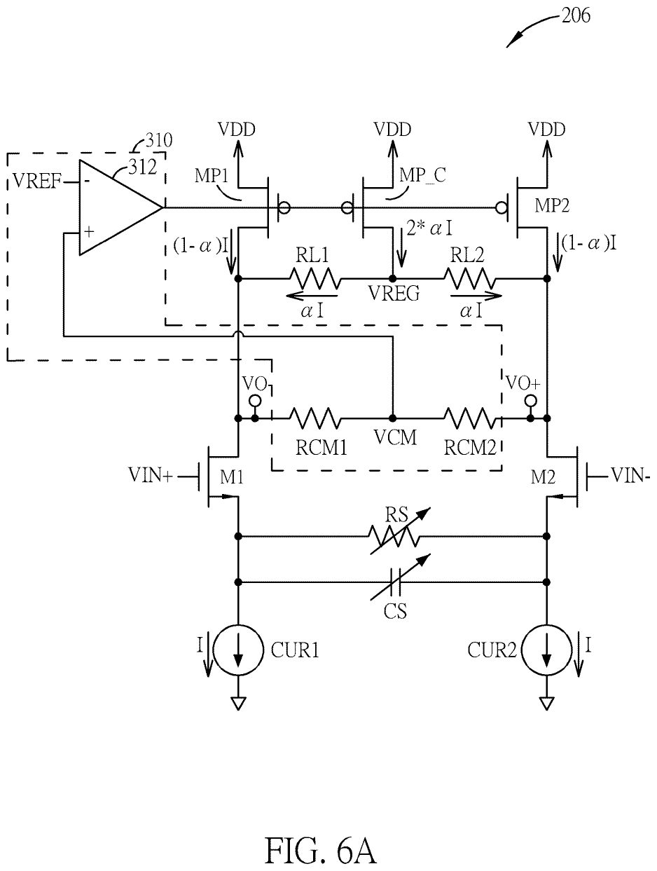

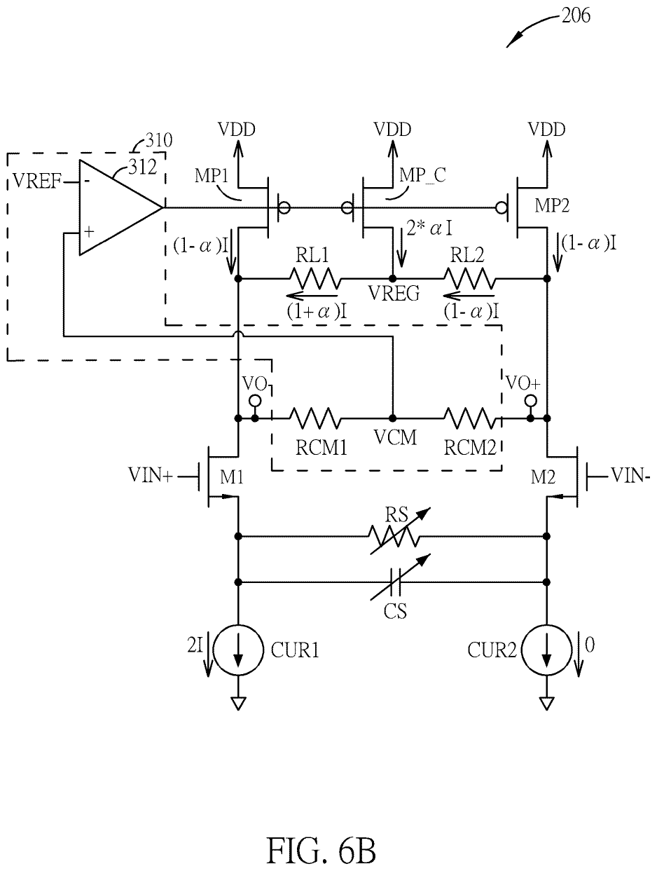

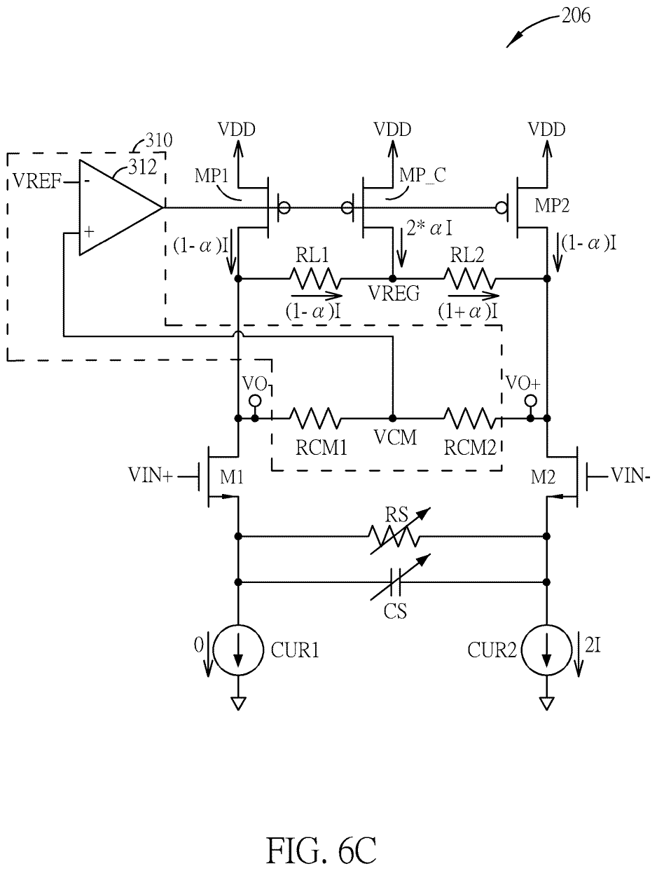

FIGS. 6A-6C are schematic diagrams of the current paths of the transmitter 206 under different scenarios. In this embodiment, it is assumed that the total current required for the operations of the transmitter 206 is 2I, with a ratio α provided by the high-side current source MP_C and the remaining ratio (1−α) equally provided by the high-side current sources MP1 and MP2. In such a situation, the current output by the high-side current source MP_C is 2αI, and each of the high-side current sources MP1 and MP2 outputs a current equal to (1−α)I. The value of α ranges between 0 and 1, and could be determined by adjusting the relative sizes of the high-side current sources MP1, MP2 and MP_C.

FIG. 6A illustrates the scenario where the input signals VIN+ and VIN− have equal voltages. In this case, the voltages of the output signals VO+ and VO− at the two output terminals may also be equal. In such a situation, each of the low-side current sources CUR1 and CUR2 conducts a current 1I, while the current output by the high-side current source MP_C is evenly distributed to the load resistors RL1 and RL2; that is, each load resistor RL1 and RL2 conducts a current αI. At this time, the voltage on the regulation node VREG is equal to:

$$VREG = 0.5 ( {VO}^{+} + {VO}^{-} ) + α IR ;$$

where VO⁺ and VO⁻ are the voltages of the output signals VO+ and VO−, respectively, and R is the resistance value of the load resistors RL1 and RL2.

FIG. 6B illustrates the scenario where the input signal VIN+ is greater than the input signal VIN−. At this time, the output signal VO+ is also greater than the output signal VO−. In such a situation, the majority of the current (close to 2I) flows through the left-side transistor M1 and the low-side current source CUR1. Consequently, the current output by the high-side current source MP_C may flow through the load resistor RL1 toward the left path, and the current output by the high-side current source MP2 may flow through both the load resistors RL2 and RL1 toward the left path. At this time, the current flowing through the load resistor RL2 is equal to (1−α) I, while the current flowing through the load resistor RL1 is equal to (1+α) I. Since the voltages of the output signals VO+ and VO− swing upward and downward with equal amplitude, the voltage of the regulation node VREG remains unchanged.

FIG. 6C illustrates the scenario where the input signal VIN− is greater than the input signal VIN+. At this time, the output signal VO− is also greater than the output signal VO+. In such a situation, the majority of the current (close to 2I) flows through the right-side transistor M2 and the low-side current source CUR2. Consequently, the current output by the high-side current source MP_C may flow through the load resistor RL2 toward the right path, and the current output by the high-side current source MP1 may flow through both the load resistors RL1 and RL2 toward the right path. At this time, the current flowing through the load resistor RL1 is equal to (1−α)I, while the current flowing through the load resistor RL2 is equal to (1+α)I. Since the voltages of the output signals VO+ and VO− swing upward and downward with equal amplitude, the voltage of the regulation node VREG remains unchanged.

As can be seen from above, regardless of how the signals swing, the voltage magnitude at the regulation node VREG remains unchanged. Therefore, through proper design of the value α, the voltage headroom of the high-side current source MP_C could be controlled within a certain range, so as to ensure that the high-side current source MP_C could operate normally across the predetermined range of the supply voltage VDD. In addition, the operation voltages of the high-side current sources MP1 and MP2 may vary respectively with voltage levels of the output signals VO− and VO+, and thus may not encounter the voltage headroom issue.

Note that the present invention aims at providing a transmitter structure for a re-driver that may be implemented by using an all-CMOS process. Those skilled in the art may make modifications and alterations accordingly. For example, the transmitter of the present invention may support a wide range of supply voltage. In the above embodiments, the supply voltage range from 1.8V to 3.3V is merely an example; in another embodiment, the operation voltage range suitable for the transmitter may be adjusted according to system requirements, and the value of the voltage range should not serve to limit the scope of the present invention. In addition, in the above embodiments, NMOS transistors are used to implement the signal transmission transistors M1 and M2 in the transmitter 206. In another embodiment, signal transmission transistors may also be implemented by using PMOS transistors. In addition, in the transmitter of the present invention, the transistor sizes, resistor values, and capacitor values may be designed according to system requirements, and their numerical values should not serve to limit the scope of the present invention.

On the other hand, in order to achieve optimal performance, the transmitter 206 structure shown in FIG. 3 is configured with three high-side current sources MP1, MP2 and MP_C. However, in another embodiment, only one or two of these high-side current sources may be used, and the transmitter structure implemented by using the all-CMOS process may still be realized. Such variations also fall within the scope of the present invention.

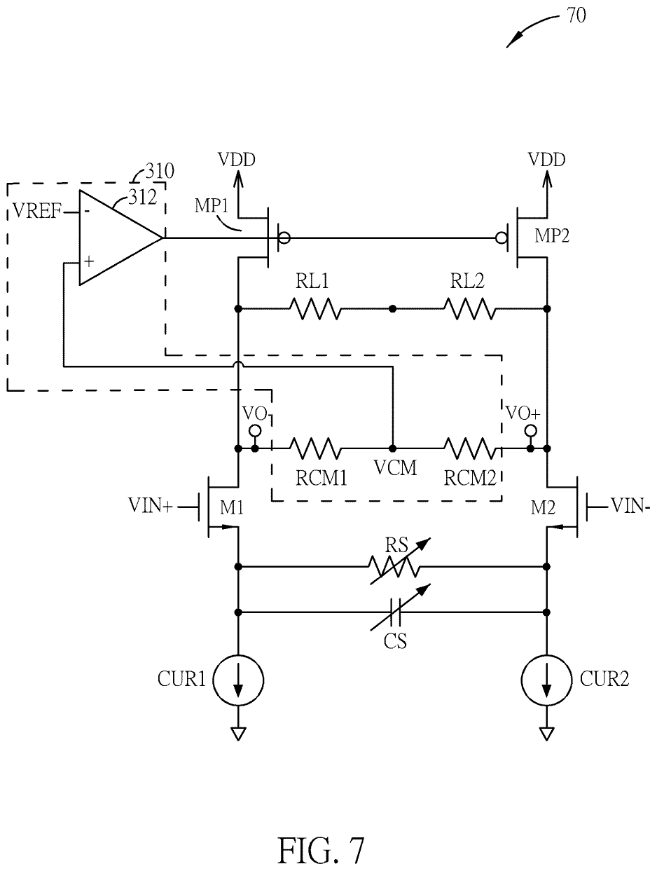

For example, FIG. 7 is a schematic diagram of another transmitter 70 according to an embodiment of the present invention. The circuit structure of the transmitter 70 is similar to that of the transmitter 206 shown in FIG. 3, so signals and elements having similar functions are denoted by the same symbols. The difference between the transmitter 70 and the transmitter 206 is that there are only two high-side current sources MP1 and MP2 included in the transmitter 70, where the central high-side current source MP_C is omitted. Although omitting the high-side current source MP_C may result in that the capacitive load of the transmitter 70 is higher than that of the transmitter 206 and thus the signal transmission speed is reduced, the inclusion of the bandwidth extension capacitor CS and the source degeneration resistor RS may still meet certain bandwidth and gain requirements. This configuration can also be used for medium-speed and high-speed signal transmission applications. In some embodiments, if the transmitter 70 is implemented by using a more advanced process, the transistor elements themselves will have lower parasitic capacitance, which mitigates the parasitic capacitance problem caused by the structure of the transmitter 70. In addition, since the transmitter 70 does not have the voltage headroom problem of the high-side current source MP_C, it may support a wider supply voltage range and lower operation voltages, offering greater advantages in terms of power consumption.

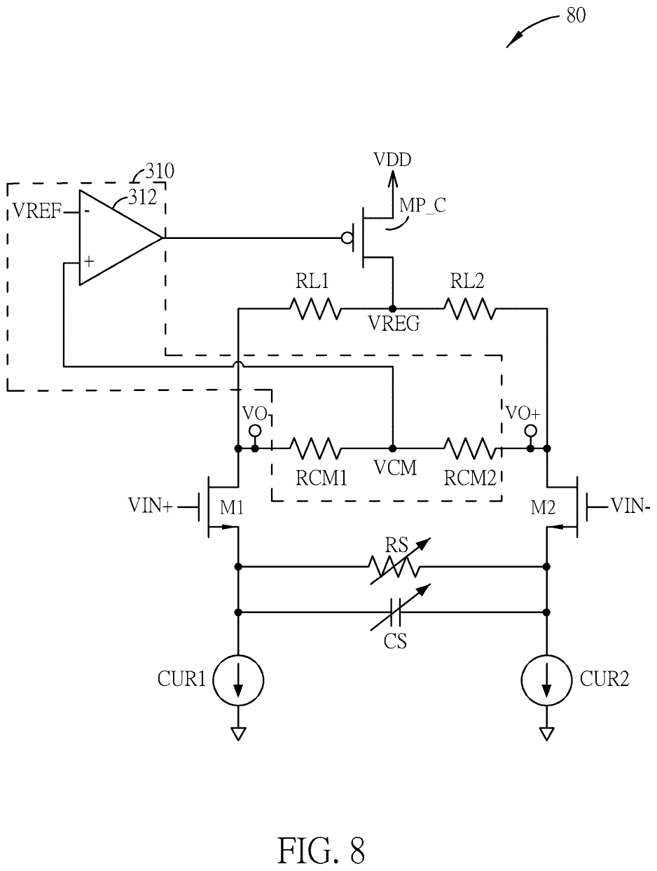

FIG. 8 is a schematic diagram of a further transmitter 80 according to an embodiment of the present invention. The circuit structure of the transmitter 80 is similar to that of the transmitter 206 shown in FIG. 3, so signals and elements having similar functions are denoted by the same symbols. The difference between the transmitter 80 and the transmitter 206 is that there is only one high-side current source MP_C included in the transmitter 80, where the high-side current sources MP1 and MP2 on left and right sides are omitted. Although omitting the high-side current sources MP1 and MP2 may result in that the transmitter 80 might have the voltage headroom problem and cannot be operated under the lower supply voltage VDD, it has a lower capacitive load and thus is able to achieve a higher bandwidth and faster signal transmission speed, so as to support ultra-speed signal transmission applications.

In one or some embodiments, if the transmitter 206 is used for high-speed transmission applications, the signal transmission transistors M1 and M2 are preferably implemented by using low-voltage devices. The low-voltage devices may be core devices in the process, which may offer faster operating speeds but usually have lower voltage tolerance. Under the scenario of a wide range supply voltage VDD, the level of the supply voltage VDD may easily exceed the tolerable voltage of the transistors M1 and M2. In such a situation, the devices in the structure of the transmitter 206 may be well designed to prevent the transistors M1 and M2 from being exposed to excessive voltages; that is, by using other components to isolate the high-speed signal transmission transistors M1 and M2 from the supply voltage VDD. This allows the supply voltage VDD to possess a relatively wide range without being constrained by the tolerable voltage of the transistors M1 and M2.

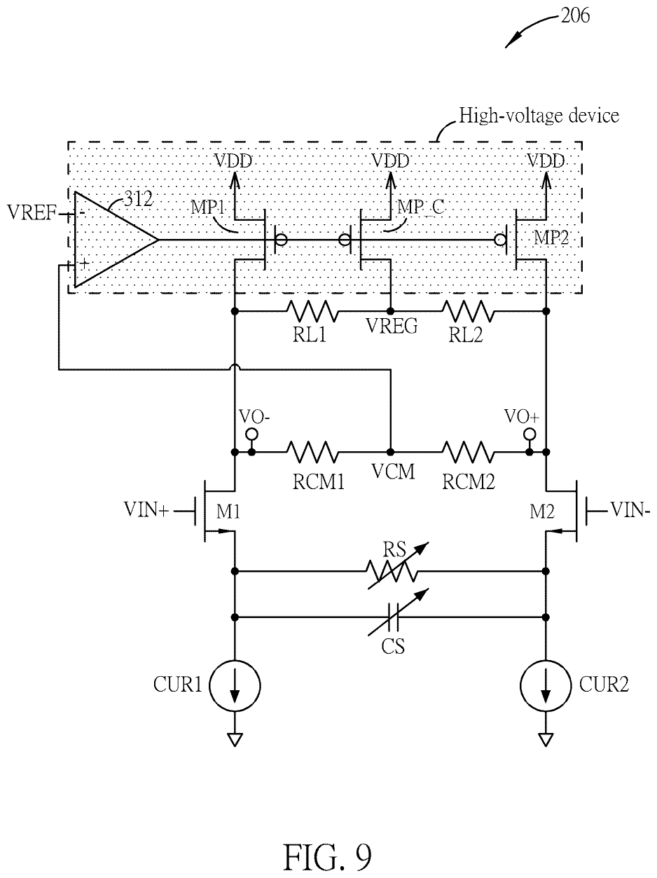

FIG. 9 illustrates an implementation of the transmitter 206 realized by using high-voltage devices and low-voltage devices. As shown in FIG. 9, the high-side current sources MP1, MP2 and MP_C and the transistors in the operational amplifier 312 operate by directly receiving the supply voltage VDD. Therefore, these devices are implemented by using the high-voltage devices capable of withstanding higher voltages. The high-voltage devices may be the I/O devices in the process, which may typically tolerate higher voltages (e.g., 3.3V or 3.6V), allowing the transmitter 206 to support the high-level supply voltage VDD and thereby achieve a wider operation voltage range. Other transistors in the transmitter 206, such as the signal transmission transistors M1 and M2 and those used to implement the low-side current sources CUR1 and CUR2, may be implemented by using low-voltage devices. Through the characteristics of high operating speed of the low-voltage devices (e.g., the core devices), the requirements for high-speed transmission could be met. In addition, the reference voltage VREF received by the common mode control circuit 310 should also have a relatively low voltage value. In this case, the common mode voltage VCM of the output signals VO+ and VO− will be at a lower level, allowing the output signals VO+ and VO− to swing within the voltage range tolerable by the low-voltage devices.

In other embodiments, the circuit elements of the transmitter 70 or 80 may also be designed in an appropriate manner to achieve both the wide voltage range and the high-speed signal transmission through the combination of high-voltage devices and low-voltage devices. The relevant implementations may be referred to the descriptions in the above paragraphs and will not be repeated herein.

To sum up, the present invention provides a transmitter implemented by using the all-CMOS process to be used for a re-driver. With the all-CMOS process, no BJTs are used, and thus there are no voltage headroom problems associated with the BJTs. This allows the transmitter to support a lower supply voltage level and a wider voltage range. In addition, in order to compensate for the problem of reduced linearity caused by the lower transconductance of the MOS transistors, a source degeneration resistor may be connected to the source terminals of the signal transmission transistors to improve the linearity. A bandwidth extension capacitor may also be added to enhance the signal bandwidth. In addition, in order to meet the requirements of a wide supply voltage range, the drain terminals of the signal transmission transistors may further be connected to one or more high-side current sources. With proper configuration of the current sources, better signal bandwidth may be obtained while the voltage headroom issues could be mitigated. As a result, the transmitter of the present invention supports a wide range of supply voltages while enabling high-linearity signal transmission.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A transmitter comprising:
a first transistor comprising a first terminal, a second terminal and a gate terminal, wherein the gate terminal of the first transistor is configured to receive a first input signal and the first terminal of the first transistor is configured to output a second output signal;
a second transistor comprising a first terminal, a second terminal and a gate terminal, wherein the gate terminal of the second transistor is configured to receive a second input signal and the first terminal of the second transistor is configured to output a first output signal;
a capacitor coupled between the second terminal of the first transistor and the second terminal of the second transistor;
a resistor coupled between the second terminal of the first transistor and the second terminal of the second transistor;
a first load resistor coupled between the first terminal of the first transistor and a first node;
a second load resistor coupled between the first terminal of the second transistor and the first node; and
a current source coupled to at least one of the first terminal of the first transistor, the first terminal of the second transistor, and the first node.

2. The transmitter of claim 1, wherein the current source comprises:
a first high-side current source coupled to the first terminal of the first transistor; and
a second high-side current source coupled to the first terminal of the second transistor.

3. The transmitter of claim 1, wherein the current source comprises:
a third high-side current source coupled to the first node.

4. The transmitter of claim 1, wherein the current source comprises:
a first high-side current source coupled to the first terminal of the first transistor;
a second high-side current source coupled to the first terminal of the second transistor; and
a third high-side current source coupled to the first node.

5. The transmitter of claim 1, wherein each of the first transistor and the second transistor is a metal-oxide semiconductor field-effect transistor (MOSFET).

6. The transmitter of claim 1, further comprising:
a common mode control circuit, comprising:
an operational amplifier;
a first common mode feedback resistor coupled between the first terminal of the first transistor and the operational amplifier; and
a second common mode feedback resistor coupled between the first terminal e second transistor and the operational amplifier.

7. The transmitter of claim 1, wherein the resistor is used for increasing a linearity of the first output signal and the second output signal.

8. The transmitter of claim 1, wherein the capacitor is used for increasing a bandwidth of the transmitter.

9. A re-driver comprising:
an equalizer;
a gain amplifier coupled to the equalizer; and
a transmitter coupled to the gain amplifier and comprising:
a first transistor comprising a first terminal, a second terminal and a gate terminal, wherein the gate terminal of the first transistor is configured to receive a first input signal and the first terminal of the first transistor is configured to output a second output signal;
a second transistor comprising a first terminal, a second terminal and a gate terminal, wherein the gate terminal of the second transistor is configured to receive a second input signal and the first terminal of the second transistor is configured to output a first output signal;
a capacitor coupled between the second terminal of the first transistor and the second terminal of the second transistor;
a resistor coupled between the second terminal of the first transistor and the second terminal of the second transistor;
a first load resistor coupled between the first terminal of the first transistor and a first node;
a second load resistor coupled between the first terminal of the second transistor and the first node; and
a current source coupled to at least one of the first terminal of the first transistor, the first terminal of the second transistor, and the first node.

10. The re-driver of claim 9, wherein the current source comprises:
a first high-side current source coupled to the first terminal of the first transistor; and
a second high-side current source coupled to the first terminal of the second transistor.

11. The re-driver of claim 9, wherein the current source comprises:
a third high-side current source coupled to the first node.

12. The re-driver of claim 9, wherein the current source comprises:
a first high-side current source coupled to the first terminal of the first transistor;
a second high-side current source coupled to the first terminal of the second transistor; and
a third high-side current source coupled to the first node.

13. The re-driver of claim 9, wherein each of the first transistor and the second transistor is a metal-oxide semiconductor field-effect transistor (MOSFET).

14. The re-driver of claim 9, wherein the transmitter further comprises:
a common mode control circuit, comprising:
an operational amplifier;
a first common mode feedback resistor coupled between the first terminal of the first transistor and the operational amplifier; and
a second common mode feedback resistor coupled between the first terminal of the second transistor and the operational amplifier.

15. The re-driver of claim 9, wherein the resistor is used for increasing a linearity of the first output signal and the second output signal.

16. The re-driver of claim 9, wherein the capacitor is used for increasing a bandwidth of the transmitter.
